(19) United States
(12) Patent Application Publication
(10) Pub. No.: US 2023/0411486 A1
(43) Pub. Date: Dec. 21, 2023

(54) Gallium Nitride Power Transistor

(71) Applicant: HUAWEI TECHNOLOGIES CO., LTD., Shenzhen (CN)

(72) Inventors: Gilberto Curatola, Nuremberg (DE); Qilong Bao, Dongguan (CN); Qimeng Jiang, Shenzhen (CN); Gaofei Tang, Shenzhen (CN); Hanxing Wang, Dongguan (CN)

(21) Appl. No.: 18/460,216

(22) Filed: Sep. 1, 2023

Related U.S. Application Data
(63) Continuation of application No. PCT/CN2021/079383, filed on Mar. 5, 2021.

(51) Int. Cl. H01L 29/47; H01L 29/20; H01L 29/778

(52) U.S. Cl. CPC H01L 29/475; H01L 29/2003; H01L 29/7786

(57) ABSTRACT

The disclosure relates to a Gallium Nitride power transistor, comprising: a buffer layer; and a barrier layer having a top side, a bottom side, the bottom side facing the buffer layer, the bottom side of the barrier layer is placed on the buffer layer; an interlayer interposed between a p-type doped Gallium Nitride layer and a metal gate layer, the interlayer is made of a III-V compound semiconductor comprising a combination of at least one group III element with at least one group V element, the p-type doped Gallium Nitride layer is placed on the top side of the barrier layer, the metal gate layer is electrically connected to the p-type doped Gallium Nitride layer via the interlayer to form a rectifying metal-semiconductor junction with the p-type doped Gallium Nitride layer.

### CROSS-REFERENCE TO RELATED APPLICATIONS

This application is a continuation of International Application No. PCT/CN2021/079383, filed on Mar. 5, 2021, the disclosure of which is hereby incorporated by reference in its entirety.

### TECHNICAL FIELD

The present disclosure relates to the field of Gallium Nitride (GaN) technology for power device applications. In particular, the disclosure relates to a Gallium Nitride power transistor, in particular, a GaN power field effect transistor (FET) with rectifying metal-semiconductor junction. The disclosure particular relates to a Schottky pGaN gate module with interlayer.

### BACKGROUND

Intensive effort has been taken in the last 15-20 years in the semiconductor industry for the development of Gallium Nitride technology as possible replacement for conventional Si-based field effect transistors. The usage of wide bandgap materials offers the possibility of unprecedented performance improvement both at device level and system level. Today, enhancement mode GaN Power FETs are becoming a reality and several main semiconductor manufacturers already have products in the market. The most mature GaN device concept, being utilized by the vast majority of players, is the pGaN normally-off concept. Two general approaches are today being followed for the fabrication of normally-off pGaN power FETs. The main difference consists in the manufacturing strategy for the metal/pGaN interface. The two possible approaches are: i) Ohmic interface; and ii) Schottky interface. In the Schottky approach a massive DC gate current reduction can be achieved, however, at the expense of two main drawbacks, which are threshold voltage instability and weakness in gate reliability.

### SUMMARY

It is the object of this disclosure to provide a solution for a GaN power transistor without the above described drawbacks of threshold voltage instability and weakness in gate reliability, or at least a GaN power transistor in which threshold voltage instability and weakness in gate reliability issues are significantly reduced.

This object is achieved by the features of the independent claims. Further implementation forms are apparent from the dependent claims, the description and the figures.

A basic idea of this disclosure is to provide a new structure for the gate module of a normally-off pGaN transistor that allows to optimize the overall performance and allows to solve the main issues of state-of-the-art pGaN Schottky gate, i.e. threshold voltage instabilities and gate reliability.

A stable pGaN Schottky Gate with Interlayer solution is presented in this disclosure, where a dedicated III-V interlayer is interposed between the pGaN layer and the metal gate. When the thickness and composition of this III-V interlayer is properly chosen, in relation to the gate stack detailed composition, it allows a stable pGaN Schottky operation and to greatly improve the threshold voltage stability and overall gate reliability.

In this disclosure, group III elements and group V elements, as well as a III-V interlayer, i.e., an interlayer made of group III-V compound semiconductors, are described. III-V compound semiconductors are obtained by combining group III elements (particularly Al, Ga, In) with group V elements (particularly N, P, As, Sb). This gives 12 possible main combinations and a further number of sub-combinations when combining one or more group III elements with one or more group V elements; examples in this disclosure are GaN, AlGaN, AlN and InAlN.

In order to describe the disclosure in detail, the following terms, abbreviations and notations will be used:
GaN Gallium-Nitride
FET Field Effect Transistor
pGaN p-doped GaN
AlGaN Aluminum Gallium-Nitride
2DEG 2-dimensional electron gas
HV high voltage (operation), e.g. >600 V
MV medium voltage (operation), e.g. 200-600 V
V_{TH} threshold voltage
TDDB time dependent dielectric breakdown

In this disclosure, two approaches in manufacturing the metal/pGaN interface are described: the Ohmic interface approach, and the Schottky interface approach.

In the Ohmic interface approach, the interface between metal gate and a pGaN surface is nearly ideal. This translates into a large DC current that sustains the device operation during on-state conditions, but also complicates the driving strategy and largely increases the driving losses.

The Ohmic interface approach provides the following advantages: (i) pGaN node is tidily connected to the gate metal terminal, thus the device is less prone to V_{TH} instability; (ii) good reliability; i.e., gate breakage is due to thermal runaway when large DC current flows through the gate; and (iii) a large amount of holea injected from the gate improves dynamic effects.

However, the following disadvantages are observed in relation to the Ohmic interface approach: (i) a large amount of holes injected into the buffer require negative off-stage gate voltages; (ii) hole accumulation might cause tail currents; (iii) dedicated driving schemes needed, e.g., current driven gate driver, or external R-C network; (iv) large DC gate current results in driving losses; and (v) limits scalability of concept to high voltage (400-600V) and to large RDSON (>30mOhm).

In the Schottky interface approach, a reverse-biased Schottky diode is inserted in series with the pn-pGaN/AlGaN diode. This allows a massive DC gate current reduction.

The Schottky interface approach provides the following advantages: (i) pGaN node is separated from the gate terminal by a reverse biased Schottky diode; (ii) low DC gate current is obtained at the expense of V_{TH} instabilities; (iii) low DC current implies a more difficult dynamic effect optimization due to lower amount of holes injected into the buffer; (iv) gate module is breaking via a TDDB mechanism (like oxide in Si-MOS devices); and (v) difficult interplay among: dynamic effects, gate reliability, and V_{TH} stability.

However, the following disadvantages are observed in relation to the Schottky interface approach: (i) the approach allows self-aligned gate concept resulting in best FOMs (figures of merit) (low C_{GS} and C_{GS}); (ii) very low, or no, DC gate current; (iii) the approach allows standard driving schemes like: voltage driven approaches, or no external RC networks; (iv) the concept can be used for both HV and MV operation; and (v) the concept allows device scaling to very low RDSON.

According to a first aspect, the disclosure relates to a Gallium Nitride power transistor, comprising: a buffer layer; a barrier layer having a top side and a bottom side, the bottom side facing the buffer layer, wherein the bottom side of the barrier layer is placed on the buffer layer; an interlayer interposed between a p-type doped Gallium Nitride layer and a metal gate layer, wherein the interlayer is made of a III-V compound semiconductor comprising a combination of at least one group III element with at least one group V element, wherein the p-type doped Gallium Nitride layer is placed on the top side of the barrier layer, wherein the metal gate layer is configured to electrically connect the p-type doped Gallium Nitride layer via the interlayer to form a rectifying metal-semiconductor junction with the p-type doped Gallium Nitride layer.

Such a GaN power transistor with rectifying metal-semiconductor junction and interlayer provides a new Schottky pGaN gate module concept, suited for enhancement mode GaN-based power transistor, which allows to have the following advantages: normally-off operation; stable threshold voltage and suppression of dynamic instabilities that characterize conventional pGaN Schottky gate approaches; and improved gate reliability thanks to strong reduction in peak electric field at the metal/pGaN interface and in pGaN bulk due to the interlayer.

In an exemplary implementation of the GaN power transistor, a gate region of the Gallium Nitride power transistor is formed by a contact region of the p-type doped Gallium Nitride layer with the barrier layer at the top side of the barrier layer.

This provides the advantage that the contact region can be precisely and selectively defined during the etching process. A further advantage is that the manufacturing process can be precisely implemented and allows producing GaN power transistors with high gate reliability.

In an exemplary implementation of the GaN power transistor, the at least one group III element comprises one of the following chemical elements: Aluminum, Gallium and Indium. In an exemplary implementation of the GaN power transistor, the at least one group V element comprises one of the following chemical elements: Nitrogen, Phosphorus, Arsenic and Antimony.

This provides the advantage that III-V compound semiconductors obtained by combining these group III elements (particularly Al, Ga, In) with group V elements (particularly N, P, As, Sb) results in wider band gap semiconductors. For example, gallium arsenide (GaAs) has six times higher electron mobility than silicon, which allows faster operation. Wider band gap allows operation of power devices at higher temperatures, and gives lower thermal noise to low power devices at room temperature.

In an exemplary implementation of the GaN power transistor, the metal gate layer is configured to electrically connect the p-type doped Gallium Nitride layer via the interlayer to form a Schottky barrier with the p-type doped Gallium Nitride layer.

This provides the advantage that by electrically connecting the p-type doped Gallium Nitride layer via the interlayer to form a Schottky barrier with the p-type doped Gallium Nitride layer, the overall performance of the power transistor is optimized while showing stable threshold voltage and reliable gate. With properly chosen thickness and composition of this III-V interlayer, the power transistor can be operated at stable pGaN Schottky operation and the threshold voltage stability and overall gate reliability is greatly improved.

In an exemplary implementation of the GaN power transistor, the interlayer comprises Aluminum-Gallium-Nitride.

Aluminum-Gallium-Nitride provides the advantage that its bandgap can be tailored in a wide range, i.e., from about 3.4 eV to about 6.2 eV. Due to its mobility, AlGaN can be efficiently used in AlGaN/GaN high-electron mobility transistors. AlGaN can be advantageously used together with gallium nitride or aluminum nitride, forming heterojunctions.

In an exemplary implementation of the GaN power transistor, the interlayer comprises Aluminum-Nitride.

Aluminum-Nitride provides the advantage of being stable at high temperatures in inert atmospheres and melts at about 2200° C. Aluminum-Nitride is stable in hydrogen and carbon-dioxide atmospheres up to 980° C. Aluminum-Nitride can be advantageously used together with Aluminum-Gallium-Nitride to form heterojunctions.

In an exemplary implementation of the GaN power transistor, the interlayer comprises Indium-Aluminum-Nitride.

Using Indium-Aluminum-Nitride provides the following advantages. Indium gallium aluminum nitride is generally prepared by epitaxial methods such as pulsed-laser deposition and molecular beam epitaxy. Addition of indium to gallium nitride to form a light-emitting layer leads to the emission of ultraviolet and visible light. Indium-Aluminum-Nitride can be advantageously used together with Aluminum-Gallium-Nitride to form heterojunctions with high electron mobility.

In an exemplary implementation of the GaN power transistor, a thickness of the interlayer is within a range of about 5 nanometers and 40 nanometers.

This provides the advantage of reduced field strength at the metal to interlayer interface resulting in stable threshold voltage of the transistor.

Exemplary thicknesses of the interlayer are the following: 5 nm, 10 nm, 15 nm, 25 nm, 30 nm, 35 nm, 40 nm, or any other values between 5 nm and 40 nm. Other values may be used as well.

In an exemplary implementation of the GaN power transistor, a content of the group III element within the III-V compound semiconductor is between about 5 percent and about 50 percent.

This provides the advantage that formation of electric field peaks at the metal to interlayer interface can be suppressed or at least significantly reduced.

Exemplary contents of group III element within the III-V compound semiconductor are 5 percent, 10 percent, 15 percent, 20 percent, 25 percent, 30 percent, 35 percent, 40 percent, percent, 50 percent, or any other percentages between 5 percent and 50 percent.

In an exemplary implementation of the GaN power transistor, a thickness of the interlayer is 5 nanometers and a content of the group III element within the III-V compound semiconductor is 5 percent.

These values provide a significant reduction of the electrical field strength at the metal-semiconductor interface, in particular at the metal to interlayer interface.

In an exemplary implementation of the GaN power transistor, a thickness of the interlayer is 20 nanometers and a content of the group III element within the III-V compound semiconductor is 5 percent.

It has shown that also these values provide a significant reduction of the electrical field strength at the metal-semiconductor interface, in particular at the metal to interlayer interface.

In an exemplary implementation of the GaN power transistor, a thickness of the interlayer is 20 nanometers and a content of the group III element within the III-V compound semiconductor is 50 percent.

It has shown that also these values provide a significant reduction of the electrical field strength at the metal-semiconductor interface, in particular at the metal to interlayer interface.

In an exemplary implementation of the GaN power transistor, the metal gate layer has a top side and a bottom side, and the interlayer has a top side and a bottom side, and the p-type doped Gallium Nitride layer has a top side and a bottom side, wherein the bottom side of the metal gate layer is placed on the top side of the interlayer; and wherein the bottom side of the interlayer is placed on the top side of the p-type doped Gallium Nitride layer.

Such a sandwich-type structure provides the advantage of efficiently constructing the rectifying metal-semiconductor junction that can be used at low field strength showing stable behavior and reliable gate electrode.

In an exemplary implementation of the GaN power transistor, the metal gate layer covers at least part of the top side of the interlayer.

This provides the advantage of flexible design. The metal gate layer can fully cover the interlayer's top side or it can cover only a central area of the interlayer, for example forming a symmetrical structure around the center or even forming an asymmetrical structure around the center.

In an exemplary implementation of the GaN power transistor, the metal gate layer is placed both, on the top side of the interlayer and on the top side of the p-type doped Gallium Nitride layer.

This provides the advantage of flexible design. The metal gate layer can fully cover the top side and each lateral side of the interlayer or the metal gate layer can cover only part of the top side and part of the lateral sides of the interlayer.

In an exemplary implementation of the GaN power transistor, the interlayer has one or more lateral sides connecting the top side of the interlayer with the bottom side of the interlayer, wherein the metal gate layer covers the top side of the interlayer and at least one of the lateral sides of the interlayer.

This provides the advantage of flexible design. The metal gate layer can cover the top side of the interlayer and one (or two or three or four) lateral sides of the interlayer.

In an exemplary implementation of the GaN power transistor, a p-type doping concentration of the p-type doped Gallium Nitride layer 112 may be less than 5e19 cm⁻³, in particular less than 1e19 cm⁻³.

Such a GaN power transistor provides a more stable design over currently available Schottky pGaN gate approaches which rely on high p-type doping concentration in the pGaN layer (>1e19 cm⁻³) and which have a typical thickness of the pGaN layer, generally, between 60 nm and 250 nm.

In an exemplary implementation, the GaN power transistor is configured to operate in normally-off operation. Thus, the GaN power transistor supports the usual method of operation at a higher threshold voltage stability and better gate reliability.

In an exemplary implementation of the GaN power transistor, the buffer layer comprises a Gallium Nitride layer or an Aluminum Gallium Nitride layer.

A buffer layer comprising GaN or AlGaN improves electron mobility of the transistor. The buffer layer further reduces reverse leakage currents in the transistor and improves on-off ratios of the transistor.

In an exemplary implementation of the GaN power transistor, the barrier layer comprises an Aluminum Gallium Nitride layer.

A transistor with such a barrier layer shows improved RF characteristics and DC performance.

According to a second aspect, the disclosure relates to a metal-semiconductor junction for a Gallium Nitride power transistor, the metal-semiconductor junction comprising: an interlayer interposed between a p-type doped Gallium Nitride layer and a metal gate layer, wherein the interlayer is made of a III-V compound semiconductor comprising a combination of at least one group III element with at least one group V element, wherein the metal gate layer is configured to electrically connect the p-type doped Gallium Nitride layer via the interlayer to form a rectifying metal-semiconductor junction with the p-type doped Gallium Nitride layer.

Such a metal-semiconductor junction of a GaN power transistor provides the following advantages: normally-off operation; stable threshold voltage and suppression of dynamic instabilities that characterize conventional pGaN Schottky gate approaches; and improved gate reliability thanks to strong reduction in peak electric field at the metal/pGaN interface and in pGaN bulk due to the interlayer.

In an exemplary implementation of the metal-semiconductor junction, the at least one group III element comprises one of the following chemical elements: Aluminum, Gallium and Indium. In an exemplary implementation of the metal-semiconductor junction, the at least one group V element comprises one of the following chemical elements: Nitrogen, Phosphorus, Arsenic and Antimony.

This provides the advantage that III-V compound semiconductors obtained by combining these group III elements (particularly Al, Ga, In) with group V elements (particularly N, P, As, Sb) results in wider band gap semiconductors. For example, gallium arsenide (GaAs) has six times higher electron mobility than silicon, which allows faster operation. Wider band gap allows operation of power devices at higher temperatures and gives lower thermal noise to low power devices at room temperature.

In an exemplary implementation of the metal-semiconductor junction, the metal gate layer is configured to electrically connect the p-type doped Gallium Nitride layer via the interlayer to form a Schottky barrier with the p-type doped Gallium Nitride layer.

This provides the advantage that by electrically connecting the p-type doped Gallium Nitride layer via the interlayer to form a Schottky barrier with the p-type doped Gallium Nitride layer, the overall performance of the metal-semiconductor junction is optimized while showing stable threshold voltage and reliable gate. With properly chosen thickness and composition of this III-V interlayer, the metal-semiconductor junction can be operated at stable pGaN Schottky operation and the threshold voltage stability and overall gate reliability is greatly improved.

In an exemplary implementation of the metal-semiconductor junction, the rectifying metal-semiconductor junction comprises a reverse biased Schottky diode for separating the p-type doped Gallium Nitride layer from the metal gate layer.

This provides the following advantages: pGaN node is separated from the gate terminal by the reverse biased Schottky diode; low DC gate current is obtained but due to the interlayer design without or at least reduced V_{TH} instabilities; improved gate reliability and V_{TH} stability.

### BRIEF DESCRIPTION OF THE DRAWINGS

Further embodiments of the disclosure will be described with respect to the following figures, in which:

FIG. 1 shows a design of a GaN power transistor with Schottky barrier according to a first example;

FIG. 2 shows a design of a GaN power transistor with Schottky barrier according to a second example;

FIG. 3 shows an equivalent circuit design for the gate module of a GaN power transistor with Schottky barrier according to the examples of the disclosure;

FIG. 4 shows an example of electric field distribution along the metal-semiconductor interface of a GaN power transistor according to the examples of the disclosure for different design parameters;

FIG. 5 shows an exemplary performance simulation of the threshold voltage stability for the pGaN Schottky gate according to the examples of the disclosure as a function of the stress time; and

FIG. 6 shows a design of a metal-semiconductor junction for a GaN power transistor according to the examples of the disclosure.

### DETAILED DESCRIPTION OF EMBODIMENTS

In the following detailed description, reference is made to the accompanying drawings, which form a part thereof, and in which is shown by way of illustration specific aspects in which the disclosure may be practiced. It is understood that other aspects may be utilized and structural or logical changes may be made without departing from the scope of the disclosure. The following detailed description, therefore, is not to be taken in a limiting sense, and the scope of the disclosure is defined by the appended claims.

It is understood that comments made in connection with a described method may also hold true for a corresponding device or system configured to perform the method and vice versa. For example, if a specific method step is described, a corresponding device may include a unit to perform the described method step, even if such unit is not explicitly described or illustrated in the figures. Further, it is understood that the features of the various exemplary aspects described herein may be combined with each other, unless specifically noted otherwise.

The semiconductor devices and systems described herein may be implemented in wireless communication schemes, in particular communication schemes according to 5G. The described semiconductor devices may be used to produce integrated circuits and/or power semiconductors and may be manufactured according to various technologies. For example, the semiconductor devices may be utilized in logic integrated circuits, analog integrated circuits, mixed signal integrated circuits, optical circuits, memory circuits and/or integrated passives.

A Schottky barrier as described in this disclosure is a potential energy barrier for electrons formed at a metal-semiconductor junction. Schottky barriers have rectifying characteristics, suitable for use as a diode. One of the primary characteristics of a Schottky barrier is the Schottky barrier height. The Schottky barrier height depends on the combination of metal and semiconductor. Not all metal—semiconductor junctions form a rectifying Schottky barrier; a metal—semiconductor junction that conducts current in both directions without rectification, perhaps due to its Schottky barrier being too low, is called an ohmic contact.

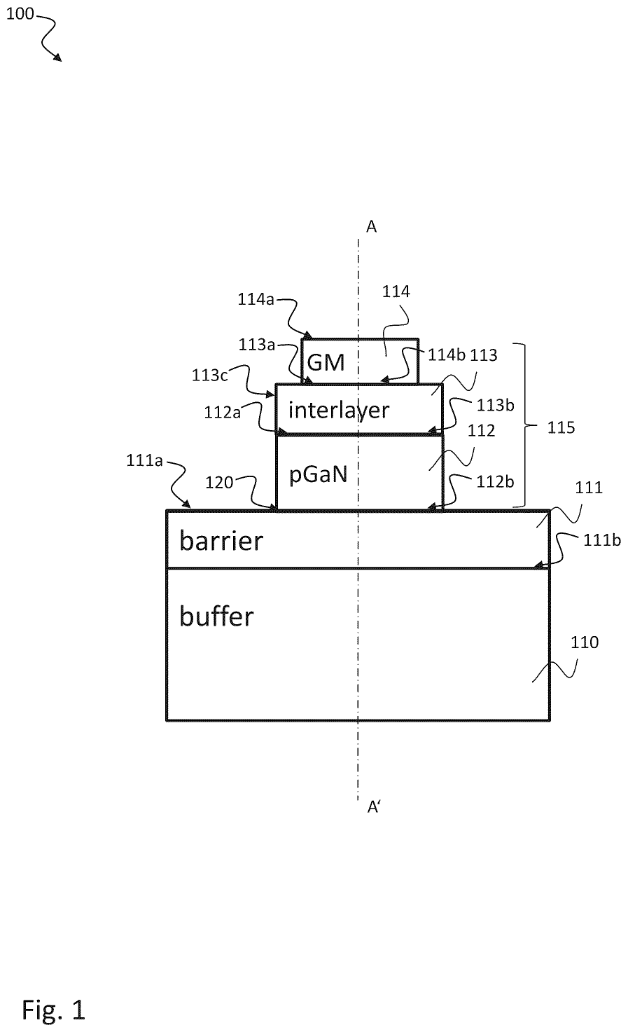

FIG. 1 shows a design of a GaN power transistor 100 with Schottky barrier according to a first example.

The Gallium Nitride power transistor 100 comprises: a buffer layer 110; and a barrier layer 111 having a top side 111a and a bottom side 111b, the bottom side 111b facing the buffer layer 110. The bottom side 111b of the barrier layer 111 is placed on the buffer layer 110.

The Gallium Nitride power transistor 100 comprises an interlayer 113 interposed between a p-type doped Gallium Nitride layer 112 and a metal gate layer 114. The interlayer 113 is made of a III-V compound semiconductor comprising a combination of at least one group III element with at least one group V element.

The p-type doped Gallium Nitride layer 112 is placed on the top side 111a of the barrier layer 111. The metal gate layer 114 is configured to electrically connect the p-type doped Gallium Nitride layer 112 via the interlayer 113 to form a rectifying metal-semiconductor junction 115 with the p-type doped Gallium Nitride layer 112.

In one example, a gate region 120 of the Gallium Nitride power transistor 100 is formed by a contact region of the p-type doped Gallium Nitride layer 112 with the barrier layer 111 at the top side 111a of the barrier layer 111, as shown in FIG. 1.

The at least one group III element may comprise one of the following chemical elements: Aluminum, Gallium and Indium. The at least one group V element may comprise one of the following chemical elements: Nitrogen, Phosphorus, Arsenic and Antimony.

The metal gate layer 114 may be configured to electrically connect the p-type doped Gallium Nitride layer 112 via the interlayer 113 to form a Schottky barrier 115 with the p-type doped Gallium Nitride layer 112.

Different designs of the interlayer 113 can be provided. In one example, the interlayer 113 comprises Aluminum-Gallium-Nitride. In one example, the interlayer 113 comprises Aluminum-Nitride. In one example, the interlayer 113 comprises Indium-Aluminum-Nitride.

In one example, a thickness of the interlayer 113 can be within a range of about 5 nanometers and 40 nanometers. In one example, a content of the group III element within the III-V compound semiconductor may be between about 5 percent and about 50 percent. In one example, a thickness of the interlayer 113 can be 5 nanometers and a content of the group III element within the III-V compound semiconductor can be 5 percent. In one example, a thickness of the interlayer 113 can be 20 nanometers and a content of the group III element within the III-V compound semiconductor can be 5 percent. In one example, a thickness of the interlayer 113 can be 20 nanometers and a content of the group III element within the III-V compound semiconductor can be 50 percent. However, other values are possible as well.

As can be seen from FIG. 1, the metal gate layer 114 has a top side 114a and a bottom side 114b, the interlayer 113 has a top side 113a and a bottom side 113b, the p-type doped Gallium Nitride layer 112 has a top side 112a and a bottom side 112b. The bottom side 114b of the metal gate layer 114 is placed on the top side 113a of the interlayer 113. The bottom side 113b of the interlayer 113 is placed on the top side 112a of the p-type doped Gallium Nitride layer 112.

In one example as can be seen in FIG. 1, the metal gate layer 114 covers at least part of the top side 113a of the interlayer 113. In one example, the metal gate layer 114 may fully cover the top side 113a of the interlayer 113.

In the example of FIG. 1, the metal gate layer 114 is placed only on the top side 113a of the interlayer 113 but not on the p-type doped Gallium Nitride layer 112. The metal gate layer 114 is not covering a top side 113a or any of the lateral sides 113c of the interlayer 113.

In one example, the buffer layer 110 may comprise a Gallium Nitride layer or an Aluminum Gallium Nitride layer.

In one example, the barrier layer 111 may comprise an Aluminum Gallium Nitride layer.

In one example of the transistor 100, the buffer layer 110 may be formed on at least one transition layer (not shown in FIG. 1) that may be formed on a Silicon substrate.

The transistor 100 further comprises a source metal layer and a drain metal layer (not shown in FIG. 1). Such source (S) metal layer and drain (D) metal layer may be formed laterally to the barrier layer 111. Source metal layer and drain metal layer may be separated by the barrier layer 111 from the pGaN layer 112, the interlayer 113 and the metal gate layer 114. In one example, source metal layer and drain metal layer may extend to the same height as the barrier layer 111.

The GaN power transistor 100 with Schottky barrier including an interlayer 113 as described above provides the following advantages: normally-off operation; stable threshold voltage and suppression of dynamic instabilities that characterize conventional pGaN Schottky gate approaches; improved gate reliability thanks to strong reduction in peak electric field at the metal/pGaN interface and in pGaN bulk

The design guidelines for such the GaN power transistor 100 can be summarized as follows: (1) insertion of a III-V interlayer between the metal layer and the pGaN layer; (2) AlGaN interlayer with: a) Thickness between 5 nm and 40 nm, and b) Al content between 5% and 40%; (3) alternative material for the interlayer can include, but are not limited to: AlN, InAlN, AlGaN.

FIG. 1 also shows a schematic representation of the newly presented gate stack for a stable and reliable pGaN Schottky device. In this newly presented approach, the III-V layer 113 is interposed between the pGaN layer 112 and the gate metal 114. When the thickness and composition of this interlayer 113 is properly chosen, it allows to improve the threshold voltage stability of conventional pGaN Schottky approach. Also, thanks to the widening of the depletion region at the metal/semiconductor interface, the presence of this interlayer 113 allows a significant electric field reduction and, hence, a drastic improvement of the overall gate reliability. Exemplary compositions of this III-V interlayer 113 are: (a) AlGaN layer with Al content ranging from 5% up to 40%; (b) AlN layer; or (c) InAlN layer.

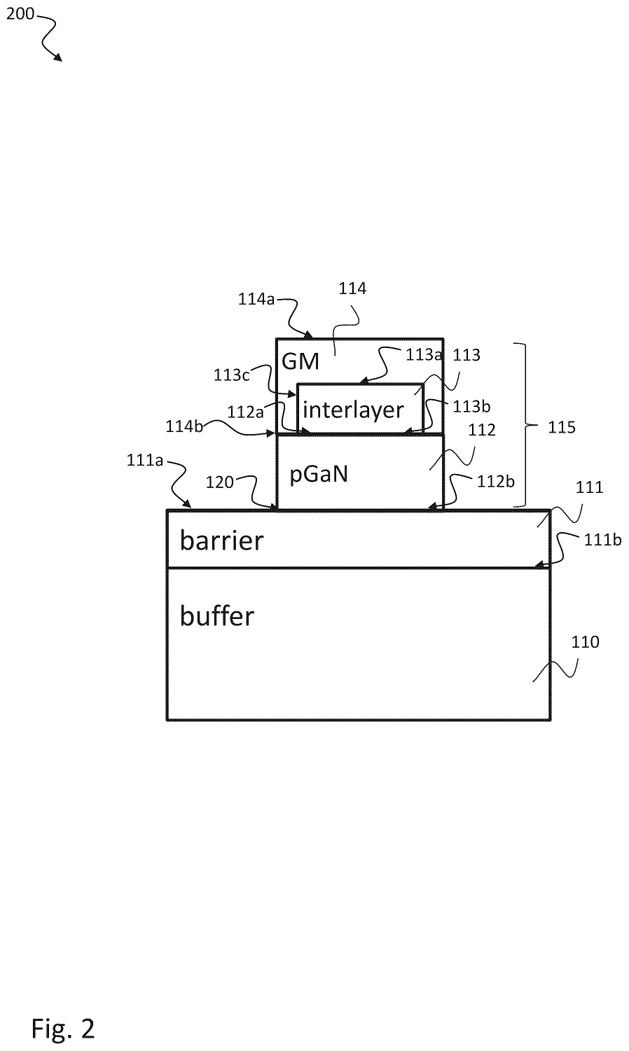

FIG. 2 shows a design of a GaN power transistor 200 with Schottky barrier according to a second example.

The GaN power transistor 200 may be designed similarly to the transistor 100 described above with respect to FIG. 1.

The Gallium Nitride power transistor 200 comprises: a buffer layer 110; and a barrier layer 111 having a top side 111a and a bottom side 111b, the bottom side 111b facing the buffer layer 110. The bottom side 111b of the barrier layer 111 is placed on the buffer layer 110.

The Gallium Nitride power transistor 200 comprises an interlayer 113 interposed between a p-type doped Gallium Nitride layer 112 and a metal gate layer 114. The interlayer 113 is made of a III-V compound semiconductor comprising a combination of at least one group III element with at least one group V element.

The p-type doped Gallium Nitride layer 112 is placed on the top side 111a of the barrier layer 111. The metal gate layer 114 is configured to electrically connect the p-type doped Gallium Nitride layer 112 via the interlayer 113 to form a rectifying metal-semiconductor junction 115 with the p-type doped Gallium Nitride layer 112.

In one example, a gate region 120 of the Gallium Nitride power transistor 200 is formed by a contact region of the p-type doped Gallium Nitride layer 112 with the barrier layer 111 at the top side 111a of the barrier layer 111, as shown in FIG. 2.

As described above, the at least one group III element may comprise one of the following chemical elements: Aluminum, Gallium and Indium. The at least one group V element may comprise one of the following chemical elements: Nitrogen, Phosphorus, Arsenic and Antimony.

As described above, the metal gate layer 114 may be configured to electrically connect the p-type doped Gallium Nitride layer 112 via the interlayer 113 to form a Schottky barrier 115 with the p-type doped Gallium Nitride layer 112.

As described above, different designs of the interlayer 113 can be provided. In one example, the interlayer 113 comprises Aluminum-Gallium-Nitride. In one example, the interlayer 113 comprises Aluminum-Nitride. In one example, the interlayer 113 comprises Indium-Aluminum-Nitride.

As described above with respect to FIG. 1, a thickness of the interlayer 113 can be within a range of about 5 nanometers and 40 nanometers. In one example, a content of the group III element within the III-V compound semiconductor may be between about 5 percent and about 50 percent. In one example, a thickness of the interlayer 113 can be 5 nanometers and a content of the group III element within the III-V compound semiconductor can be 5 percent. In one example, a thickness of the interlayer 113 can be 20 nanometers and a content of the group III element within the III-V compound semiconductor can be 5 percent. In one example, a thickness of the interlayer 113 can be 20 nanometers and a content of the group III element within the III-V compound semiconductor can be 50 percent. However, other values are possible as well.

As can be seen from FIG. 2, the metal gate layer 114 has a top side 114a and a bottom side 114b, the interlayer 113 has a top side 113a and a bottom side 113b, the p-type doped Gallium Nitride layer 112 has a top side 112a and a bottom side 112b. The bottom side 114b of the metal gate layer 114 is placed on the top side 113a of the interlayer 113. The bottom side 113b of the interlayer 113 is placed on the top side 112a of the p-type doped Gallium Nitride layer 112.

In FIG. 2, the bottom side 114b of the metal gate layer 114 is placed on the top side 113a of the interlayer 113; and the bottom side 113b of the interlayer 113 is placed on the top side 112a of the p-type doped Gallium Nitride layer 112.

The metal gate layer 114 may cover at least part of the top side 113a of the interlayer 113 or may fully cover the top side 113a of the interlayer 113 as shown in FIG. 2.

As shown in FIG. 2, the metal gate layer 114 can be placed both, on the top side 113a of the interlayer 113 and on the top side 112a of the p-type doped Gallium Nitride layer 112.

In the example of FIG. 2, the interlayer 113 has one or more lateral sides 113c connecting the top side 113a of the interlayer 113 with the bottom side 113b of the interlayer 113. The metal gate layer 114 can cover the top side 113a of the interlayer 113 and at least one of the lateral sides 113c of the interlayer 113. In the example of FIG. 2, the metal gate layer 114 covers both, the top side 113a of the interlayer 113 and all lateral sides 113c of the interlayer 113.

The buffer layer 110 may comprise a Gallium Nitride layer or an Aluminum Gallium Nitride layer. The barrier layer 111 may comprise an Aluminum Gallium Nitride layer.

As described above with respect to FIG. 1, the buffer layer 110 may be formed on at least one transition layer (not shown in FIG. 2) that may be formed on a Silicon substrate.

The transistor 200 further comprises a source metal layer and a drain metal layer (not shown in FIG. 2). Such source (S) metal layer and drain (D) metal layer may be formed laterally to the barrier layer 111, as described above with respect to FIG. 1. Source metal layer and drain metal layer may be separated by the barrier layer 111 from the pGaN layer 112, the interlayer 113 and the metal gate layer 114. In one example, source metal layer and drain metal layer may extend to the same height as the barrier layer 111.

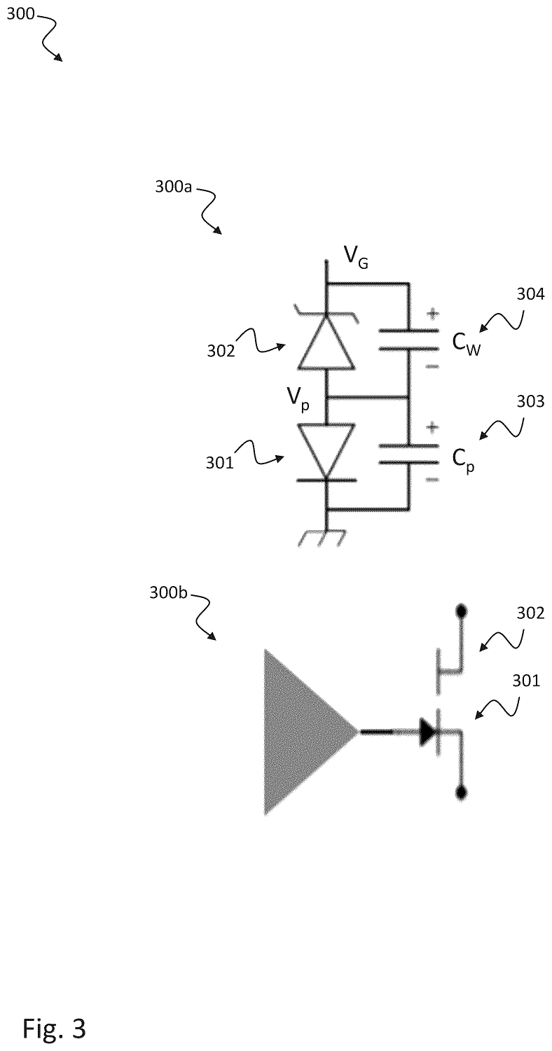

FIG. 3 shows an equivalent circuit design 300 for the gate module of a GaN power transistor with Schottky barrier according to the disclosure.

In the Schottky approach as shown in FIG. 3, a reverse-biased Schottky diode 302 is inserted in series with the pn-pGaN/AlGaN diode 301 as shown in the driving scheme 300b. This allows a massive DC gate current reduction. The series connection of the reverse-biased Schottky diode 302 with its parallel connected capacitance Cw 304 and the pn-pGaN/AlGaN diode 301 with its parallel connected capacitance Cp 303 is illustrated in the equivalent circuit 300a.

Threshold voltage instabilities (positive and negative) are observed in the Schottky approach which can make the device more prone to spurious turn-on effects (for negative V_{TH} shift) or degrade the device on-state resistance (for positive V_{TH} shift). A threshold voltage dynamic behavior can be observed for a pGaN Schottky gate, for example in case of positive stress voltage applied to the gate electrode.

Weak gate robustness is also observed for the Schottky approach. A time dependent dielectric breakdown (TDDB) behavior is observed, similarly to the breakage of gate dielectrics in conventional Si-based power devices. Several theories have been proposed to explain the gate failure mechanisms and one possible root cause has been identified as impact ionization effects, within the depletion region of the reversed biased Schottky diode, triggered by electrons injected from the AlGaN barrier into the pGaN layer. Tests with the electric field distribution within the pGaN layer under positive voltage applied to the gate electrode have shown that the maximum electric field is located at the metal/pGaN interface.

Most Schottky gate pGaN approaches today rely on very high p-type doping concentration in the pGaN layer (>5e19 cm⁻³). The typical thickness of the pGaN layer is, generally, between 60 nm and 250 nm. The p-type doping concentration can be extracted via conventional SIMs profile measurements.

It has been demonstrated that hole depletion and accumulation (which are time dependent and geometry dependent) causes threshold voltage instability. Moreover, the very high doping concentration used in the pGaN layer induces a very narrow depletion region at the metal/pGaN interface. A main drawback of this approach is that the electric field within the narrow depletion region reaches very high values (˜5-10MV/cm) and can strongly compromise the overall gate reliability. It is believed that the high electric field in the depletion region causes strong acceleration of electrons injected from the 2DEG into the pGaN layer. Those accelerated electrons can promote carrier multiplication via impact ionization effects and the presence of large number of highly energetic carriers, may damage (e.g., percolation paths) the metal/pGaN interface and, eventually, compromise the overall gate reliability.

Several attempts have been investigated in the past years to improve the gate reliability of pGaN gate modules and to alleviate the threshold voltage instabilities of pGaN Schottky gate. For example, a direct correlation between the static DC gate current and the overall gate reliability has been observed. The reduction of the static gate current, unfortunately, translates into higher threshold voltage instabilities due to the presence of a large amount of floating holes in the pGaN layer that can be injected into the AlGaN barrier and/or recombine with electrons injected from the 2DEG into the pGaN layer, without being replenished by the metal gate electrode.

For the aforementioned reasons, the disclosure presents a solution how to overcome the above described drawbacks of pGaN Schottky gate modules, which are: large positive and negative threshold voltage instabilities; and poor gate reliability.

The solution according to the disclosure is to provide a new structure for the gate module of a normally-off pGaN transistor that allows to optimize the overall performance and allow to solve the main issues of state-of-the-art pGaN Schottky gate, i.e., threshold voltage instabilities and gate reliability. A stable pGaN Schottky Gate with Interlayer solution is presented in this disclosure, where a dedicated III-V interlayer is interposed between the pGaN layer and the metal gate. When the thickness and composition of this III-V interlayer is properly chosen, in relation to the gate stack detailed composition, a stable pGaN Schottky operation can be provided and the threshold voltage stability and overall gate reliability are greatly improved.

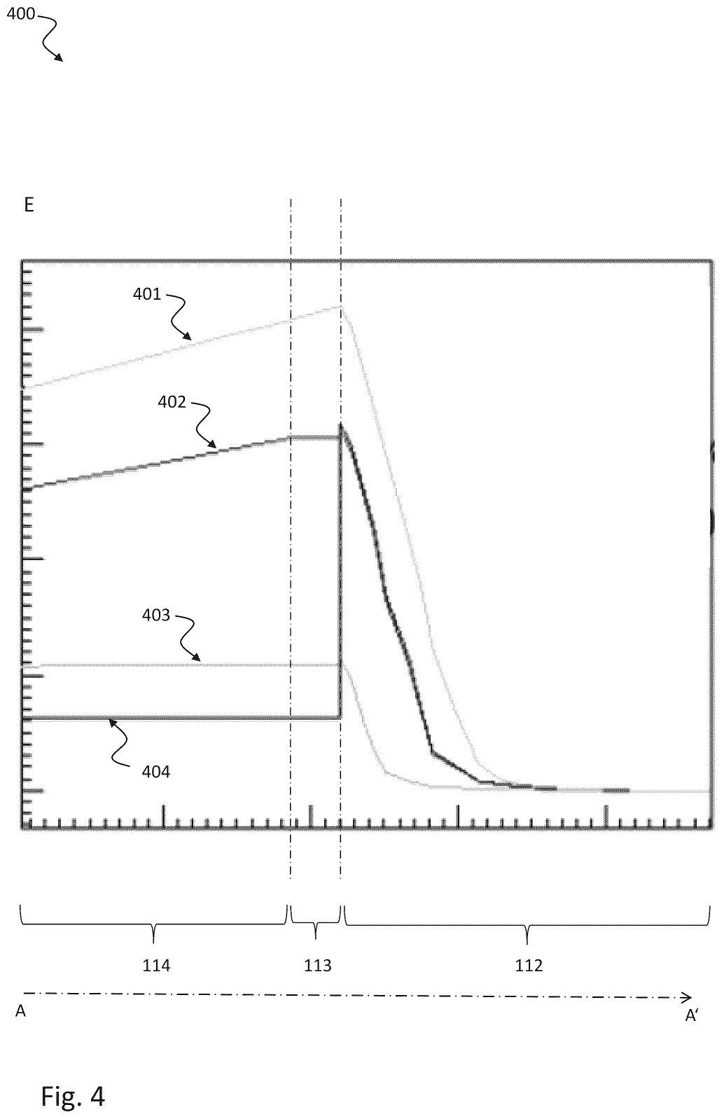

FIG. 4 shows an example of electric field distribution 400 along the metal-semiconductor interface of a GaN power transistor according to the disclosure for different design parameters. In particular, the 1D electric field distribution along the A-A′ cutline, shown in FIG. 1, for the pGaN Schottky gate stack under positive gate stress is illustrated. The four different gate stack configurations are considered:
(i) Conventional pGaN Schottky interface, graph 401;
(ii) interlayer according to a first design parameter configuration, graph 402;
(iii) interlayer according to a second design parameter configuration, graph 403;
(iv) interlayer according to a third design parameter configuration, graph 404.

The metal-semiconductor interface along the A-A′ cutline is partitioned into three sections. A first section 114 illustrates the extension of the metal gate layer 114 as shown in FIG. 1. A second section 113 illustrates the extension of the interlayer 113 as shown in FIG. 1. A third section 112 illustrates the extension of the metal gate layer 114 as shown in FIG. 1.

The electric field distribution 400 of FIG. 4 shows that, compared to the conventional pGaN Schottky gate stack 401, a massive reduction of the electric field can be achieved with the insertion of a III-V interlayer (e.g., graphs 402, 403, 404). It can be observed that, by inserting a III-V interlayer 113 according to different design parameter configurations, the reduction of the electric field peak at the metal/semiconductor interface is more pronounced.

It can also be observed that, when applying a specific design parameter configuration (see, e.g., graph 404), due to the presence of the polarization charges at the interlayer/pGaN interface, there is the formation of an electron inversion layer and the sudden appearance of another electric field peak, this time located at the interlayer/pGaN interface 113/112. Based on those consideration, the interlayer 113 thickness and composition can be chosen in such a way to avoid the latter case considered.

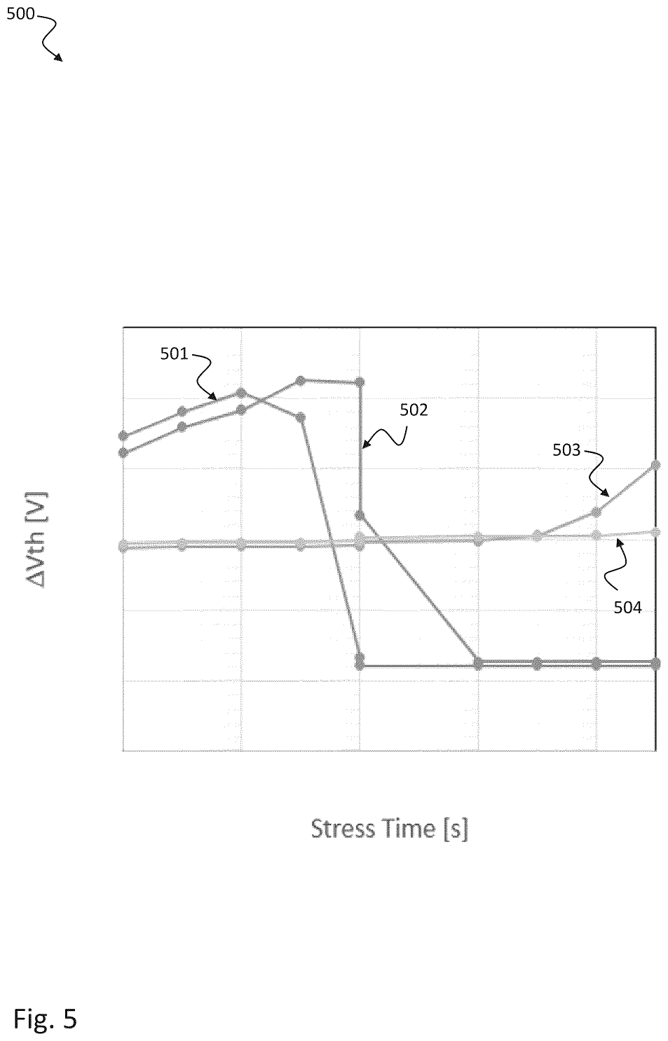

FIG. 5 shows an exemplary performance simulation 500 of the threshold voltage stability for the pGaN Schottky gate according to the disclosure as a function of the stress time. FIG. 5 particularly shows the simulated dynamic threshold voltage of the pGaN Schottky gate as a function of the stress time applied to the gate electrode and for different interlayer configuration. The case of a conventional pGaN Schottky gate without interlayer is shown for comparison.

FIG. 5 shows the simulated threshold voltage dynamic variation, under positive gate stress applied to the gate stack, for different stress time considered. Again, the four different gate stack configurations as shown in FIG. 4 are considered:
(i) Conventional pGaN Schottky interface, graph 501;
(ii) interlayer according to a first design parameter configuration, graph 502;
(iii) interlayer according to a second design parameter configuration, graph 503;
(iv) interlayer according to a third design parameter configuration, graph 504.

It can be observed that in case of conventional pGaN Schottky gate (e.g., graph 501), the device threshold voltage experiences both positive and negative variation. Those V_{TH} instabilities have been largely confirmed by experiments and simulations, already extensively published in the literature. FIG. 5 also shows that, in case of the presence of an interlayer 113, e.g. according to FIGS. 1 and 2, if a specific design parameter configuration is used, e.g., for case (ii), the impact and improvement on the dynamic threshold voltage instabilities is marginal, as can be seen by graph 502. On the other side, when other design parameter configurations are used, e.g., as in cases (iii) and (iv), a drastic improvement on the V_{TH} instabilities can be achieved, as can be seen for graphs 503 and 504. It can be observed that a III-V interlayer 113 as described in this disclosure allows to achieve a stable threshold voltage V_{TH} even in case of long stress time.

In summary, the performance simulation 500 of the threshold voltage stability for the pGaN Schottky gate in FIG. 5 show as a result that the detailed composition of the III-V interlayer 113 can be chosen in such a way that it is possible to obtain, at the same time, a drastic reduction in the electric field peak at the metal/semiconductor interface as well as to suppress the dynamic threshold voltage instabilities that affect conventional pGaN Schottky gate approaches.

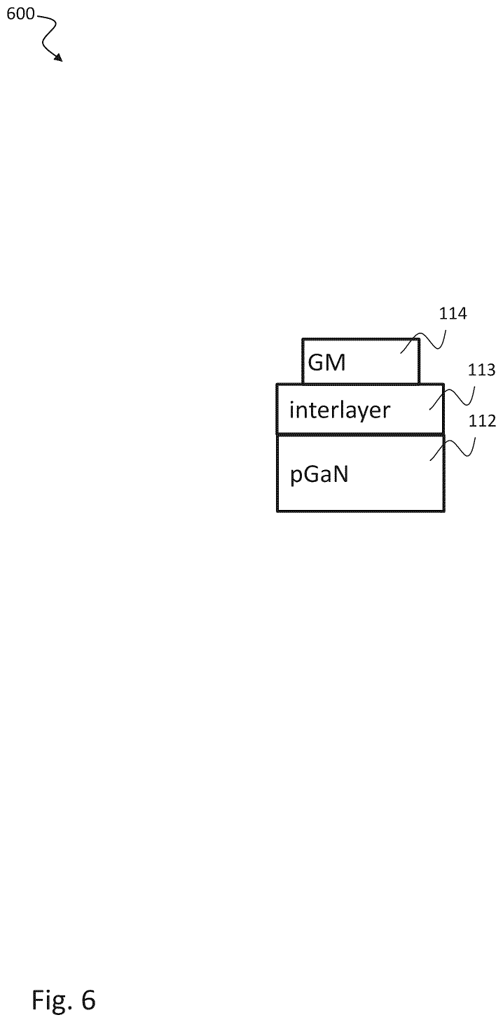

FIG. 6 shows a design of a metal-semiconductor junction 600 for a GaN power transistor according to the disclosure.

The metal-semiconductor junction 600 comprises an interlayer 113 interposed between a p-type doped Gallium Nitride layer 112 and a metal gate layer 114, e.g., according to the structure 115 shown in FIGS. 1 and 2. The interlayer 113 is made of a III-V compound semiconductor comprising a combination of at least one group III element with at least one group V element. The metal gate layer 114 is configured to electrically connect the p-type doped Gallium Nitride layer 112 via the interlayer 113 to form a rectifying metal-semiconductor junction 115 with the p-type doped Gallium Nitride layer 112.

In one example, the at least one group III element may comprise one of the following chemical elements: Aluminum, Gallium and Indium. In one example, the at least one group V element may comprise one of the following chemical elements: Nitrogen, Phosphorus, Arsenic and Antimony.

The metal gate layer 114 may be configured to electrically connect the p-type doped Gallium Nitride layer 112 via the interlayer 113 to form a Schottky barrier 115 with the p-type doped Gallium Nitride layer 112.

The rectifying metal-semiconductor junction 115 may comprise a reverse biased Schottky diode 302 for separating the p-type doped Gallium Nitride layer 112 from the metal gate layer 114, e.g., according to the design 300 shown in FIGS. 3a and 3b.

While a particular feature or aspect of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Also, the terms “exemplary”, “for example” and “e.g.” are merely meant as an example, rather than the best or optimal. The terms “coupled” and “connected”, along with derivatives may have been used. It should be understood that these terms may have been used to indicate that two elements cooperate or interact with each other regardless whether they are in direct physical or electrical contact, or they are not in direct contact with each other.

Although specific aspects have been illustrated and described herein, it will be appreciated by those of ordinary skill in the art that a variety of alternate and/or equivalent implementations may be substituted for the specific aspects shown and described without departing from the scope of the disclosure. This application is intended to cover any adaptations or variations of the specific aspects discussed herein.

Although the elements in the following claims are recited in a particular sequence with corresponding labeling, unless the claim recitations otherwise imply a particular sequence for implementing some or all of those elements, those elements are not necessarily intended to be limited to being implemented in that particular sequence.

Many alternatives, modifications, and variations will be apparent to those skilled in the art in light of the above teachings. Of course, those skilled in the art readily recognize that there are numerous applications of the disclosure beyond those described herein. While the disclosure has been described with reference to one or more particular embodiments, those skilled in the art recognize that many changes may be made thereto without departing from the scope of the present disclosure. It is therefore to be understood that within the scope of the appended claims and their equivalents, the disclosure may be practiced otherwise than as specifically described herein.

What is claimed is:

1. A Gallium Nitride power transistor, comprising:
a buffer layer;
a barrier layer having a top side and a bottom side, the bottom side facing the buffer layer, wherein the bottom side of the barrier layer is disposed on the buffer layer; and
an interlayer interposed between a p-type doped Gallium Nitride layer and a metal gate layer, wherein the interlayer is made of a III-V compound semiconductor comprising a combination of at least one group III element with at least one group V element,
wherein the p-type doped Gallium Nitride layer is disposed on the top side of the barrier layer, and
wherein the metal gate layer is configured to electrically connect the p-type doped Gallium Nitride layer via the interlayer to form a rectifying metal-semiconductor junction with the p-type doped Gallium Nitride layer.

2. The Gallium Nitride power transistor according to claim 1,
wherein a gate region of the Gallium Nitride power transistor is formed by a contact region of the p-type doped Gallium Nitride layer with the barrier layer at the top side of the barrier layer.

3. The Gallium Nitride power transistor according to claim 1,
wherein the at least one group III element comprises one of the following chemical elements: Aluminum, Gallium, and Indium.

4. The Gallium Nitride power transistor according to claim 1,
wherein the at least one group V element comprises one of the following chemical elements: Nitrogen, Phosphorus, Arsenic, and Antimony.

5. The Gallium Nitride power transistor according to claim 1,
wherein the metal gate layer is configured to electrically connect the p-type doped Gallium Nitride layer via the interlayer to form a Schottky barrier with the p-type doped Gallium Nitride layer.

6. The Gallium Nitride power transistor according to claim 1,
wherein the interlayer comprises Aluminum-Gallium-Nitride.

7. The Gallium Nitride power transistor according to claim 1,
wherein the interlayer comprises Aluminum-Nitride.

8. The Gallium Nitride power transistor according to claim 1,
wherein the interlayer comprises Indium-Aluminum-Nitride.

9. The Gallium Nitride power transistor according to claim 1,
wherein a thickness of the interlayer is within a range of 5 nanometers to 40 nanometers.

10. The Gallium Nitride power transistor according to claim 1,
wherein a content of the group III element within the III-V compound semiconductor is between 5 percent and 50 percent.

11. The Gallium Nitride power transistor according to claim 1,
wherein a thickness of the interlayer is 5 nanometers and a content of the group III element within the III-V compound semiconductor is 5 percent.

12. The Gallium Nitride power transistor according to claim 1,
wherein a thickness of the interlayer is 20 nanometers and a content of the group III element within the III-V compound semiconductor is 5 percent.

13. The Gallium Nitride power transistor according to claim 1,
wherein a thickness of the interlayer is 20 nanometers and a content of the group III element within the III-V compound semiconductor is 50 percent.

14. The Gallium Nitride power transistor according to claim 1,
wherein the metal gate layer has a top side and a bottom side,
wherein the interlayer has a top side and a bottom side,
wherein the p-type doped Gallium Nitride layer has a top side and a bottom side,
wherein the bottom side of the metal gate layer is disposed on the top side of the interlayer; and
wherein the bottom side of the interlayer is disposed on the top side of the p-type doped Gallium Nitride layer.

15. The Gallium Nitride power transistor according to claim 14,
wherein the metal gate layer covers at least part of the top side of the interlayer.

16. The Gallium Nitride power transistor according to claim 14,
wherein the metal gate layer is disposed both, on the top side of the interlayer and on the top side of the p-type doped Gallium Nitride layer.

17. The Gallium Nitride power transistor according to claim 14,
wherein the interlayer has one or more lateral sides connecting the top side of the interlayer with the bottom side of the interlayer, and
wherein the metal gate layer covers the top side of the interlayer and at least one of the lateral sides of the interlayer.

18. The Gallium Nitride power transistor according to claim 1,
wherein the buffer layer comprises a Gallium Nitride layer or an Aluminum Gallium Nitride layer.

19. The Gallium Nitride power transistor according to claim 1,
wherein the barrier layer comprises an Aluminum Gallium Nitride layer.

20. A metal-semiconductor junction for a Gallium Nitride power transistor, the metal-semiconductor junction comprising:
an interlayer interposed between a p-type doped Gallium Nitride layer and a metal gate layer, wherein the interlayer is made of a III-V compound semiconductor comprising a combination of at least one group III element with at least one group V element, and
wherein the metal gate layer is configured to electrically connect the p-type doped Gallium Nitride layer via the interlayer to form a rectifying metal-semiconductor junction with the p-type doped Gallium Nitride layer.

21. The metal-semiconductor junction according to claim 20,
wherein the at least one group III element comprises one of the following chemical elements: Aluminum, Gallium, and Indium.

22. The metal-semiconductor junction according to claim 20,
wherein the at least one group V element comprises one of the following chemical elements: Nitrogen, Phosphorus, Arsenic, and Antimony.

23. The metal-semiconductor junction according to claim 20,
wherein the metal gate layer is configured to electrically connect the p-type doped Gallium Nitride layer via the interlayer to form a Schottky barrier with the p-type doped Gallium Nitride layer.

24. The metal-semiconductor junction according to claim 20,
wherein the rectifying metal-semiconductor junction comprises a reverse biased Schottky diode for separating the p-type doped Gallium Nitride layer from the metal gate layer.
